(19) United States
(12) Patent Application Publication
(10) Pub. No.: US 2024/0204150 A1
(43) Pub. Date: Jun. 20, 2024

(54) LIGHT-EMITTING DEVICE

(71) Applicant: NICHIA CORPORATION, Anan-shi (JP)

(72) Inventor: Yusuke KAWANO, Anan-shi (JP)

(21) Appl. No.: 18/539,599

(22) Filed: Dec. 14, 2023

(30) Foreign Application Priority Data
Dec. 15, 2022 (JP) 2022-199897

(51) Int. Cl. H01L 33/50; H01L 33/62

(52) U.S. Cl. CPC H01L 33/505; H01L 33/62

(57) ABSTRACT

A light-emitting device includes a light source, a light-transmissive member, and a covering member. A second surface of the light-transmissive member faces an upper surface of the light source. The covering member exposes a first surface of the light-transmissive member and covering lateral surfaces of the light-transmissive member and the light source. In a top view, a center of the upper surface of the light source is located closer to a side of a second lateral surface of the light-transmissive member than a center of the first surface of the light-transmissive member, and a length from a first lateral surface of the light source to a first lateral surface of the light-transmissive member is equal to or greater than ¼ of a length from the first lateral surface of the light-transmissive member to the second lateral surface of the light-transmissive member.

### CROSS-REFERENCE TO RELATED APPLICATION

This application claims priority to Japanese Patent Application No. 2022-199897 filed on Dec. 15, 2022, the disclosures of which are hereby incorporated by reference in their entireties.

The present disclosure relates to a light-emitting device.

In recent years, LEDs have been used as light sources for vehicle lamps such as headlights. For example, Japanese Patent Publication No. 2014-239140 discloses a light-emitting device including a light-emitting element, a phosphor plate placed on an upper surface of the light-emitting element, a sealing resin disposed so that an upper surface of the phosphor plate is exposed, and a diffusion resin covering the upper surface of the phosphor plate and an upper surface of a resin body. Japanese Patent Publication No. 2016-072515 discloses a light-emitting device including a light-emitting element, a wavelength conversion member joined to a top face of the light-emitting element, a light-transmissive member having a larger area than the top face of the light-emitting element and disposed on a top face of the wavelength conversion member, a lateral surface light guide member having transmissivity, and a light-reflective member disposed on at least on lateral surfaces of the wavelength conversion member, the light-transmissive member, and the lateral surface light guide member.

### SUMMARY

An object of the present disclosure is to provide a light-emitting device including a high brightness region partially on a light-emitting surface.

A light-emitting device according to an embodiment of the present disclosure includes a light source, a light-transmissive member, and a covering member. The light source includes a light-emitting element, the light source having a light-emitting surface on an upper surface. The light-transmissive member includes a first surface and a second surface located on an opposite side of the first surface. The second surface of the light-transmissive member faces the upper surface of the light source. The covering member exposes the first surface of the light-transmissive member and covering lateral surfaces of the light-transmissive member and lateral surfaces of the light source. The lateral surfaces of the light source include a first lateral surface continuous with the upper surface and a second lateral surface located on an opposite side of the first lateral surface. The lateral surfaces of the light-transmissive member include a first lateral surface located on the same side as the first lateral surface of the light source and a second lateral surface located on an opposite side of the first lateral surface. In a top view, a center of the upper surface of the light source is located closer to a side of the second lateral surface of the light-transmissive member than a center of the first surface of the light-transmissive member, and a length from the first lateral surface of the light source to the first lateral surface of the light-transmissive member is equal to or greater than ¼ of a length from the first lateral surface of the light-transmissive member to the second lateral surface of the light-transmissive member.

An embodiment according to the present disclosure can provide a light-emitting device including a high brightness region partially on a light-emitting surface.

### BRIEF OF DESCRIPTION OF DRAWINGS

FIG. 1A is a perspective view schematically illustrating a light-emitting device according to a first embodiment.

FIG. 1B is a top view schematically illustrating the light-emitting device according to the first embodiment.

FIG. 1C is a cross-sectional view schematically illustrating a cross section taken along line IC-IC of FIG. 1B.

FIG. 1D is a bottom view schematically illustrating the light-emitting device according to the first embodiment.

FIG. 2 is a cross-sectional view schematically illustrating a light path from a light source of the light-emitting device according to the first embodiment.

FIG. 3 is a flowchart of a method for manufacturing the light-emitting device according to the first embodiment.

FIG. 4A is a top view schematically illustrating the method for manufacturing the light-emitting device according to the first embodiment.

FIG. 4B is a top view schematically illustrating the method for manufacturing the light-emitting device according to the first embodiment.

FIG. 4C is a cross-sectional view schematically illustrating the method for manufacturing the light-emitting device according to the first embodiment.

FIG. 4D is a cross-sectional view schematically illustrating the method for manufacturing the light-emitting device according to the first embodiment.

FIG. 4E is a cross-sectional view schematically illustrating the method for manufacturing the light-emitting device according to the first embodiment.

FIG. 4F is a cross-sectional view schematically illustrating the method for manufacturing the light-emitting device according to the first embodiment.

FIG. 5A is a top view schematically illustrating a light-emitting device according to a second embodiment.

FIG. 5B is a cross-sectional view schematically illustrating a cross section taken along line VB-VB of FIG. 5A.

FIG. 6 is a cross-sectional view schematically illustrating a light-emitting device according to a third embodiment.

FIG. 7 is a cross-sectional view schematically illustrating a light-emitting device according to a fourth embodiment.

FIG. 8 is a cross-sectional view schematically illustrating a light-emitting device according to a fifth embodiment.

FIG. 9 is a cross-sectional view schematically illustrating a light-emitting device according to a sixth embodiment.

FIG. 10 is a cross-sectional view schematically illustrating a light-emitting device according to a seventh embodiment.

### EMBODIMENTS

Embodiments are described below with reference to the drawings. The following embodiments are examples of light-emitting devices and methods for manufacturing the light-emitting devices to embody the technical concept of the present embodiment, and the present embodiment is not limited to the embodiments described below. Unless otherwise specified, dimensions, materials, shapes, relative arrangements, or the like of components described in the embodiments are not intended to limit the scope of the present invention thereto and are merely exemplary. Sizes, positional relationships, and the like of members illustrated in the drawings can be exaggerated or simplified for clarity of description. To avoid overcomplicating the drawings, some elements may be omitted or end views illustrating only cut surfaces may be used as cross-sectional views. Furthermore, “covering” is not limited to cases of direct contact, but also includes cases of indirectly covering a member, for example, via another member. Furthermore, “disposing” includes not only a case of disposing by direct contact but also a case of indirectly disposing, for example, via another member. Note that “top view” in the present specification means observation from the side of an upper surface that is a light-emitting surface of the light-emitting device.

### First Embodiment

### Light-Emitting Device

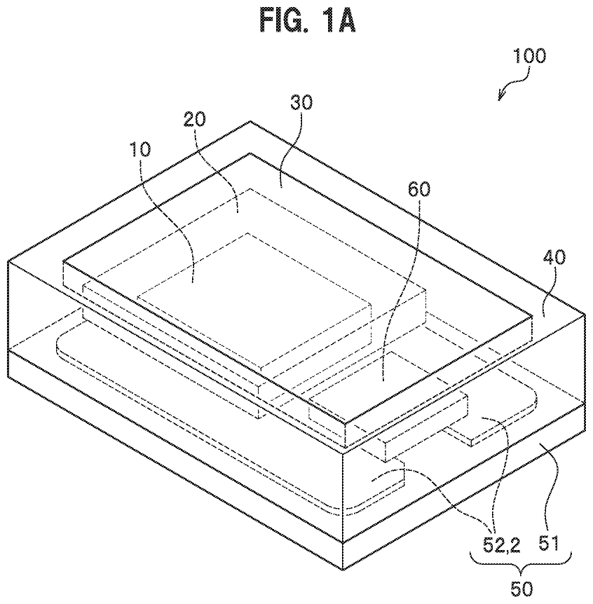

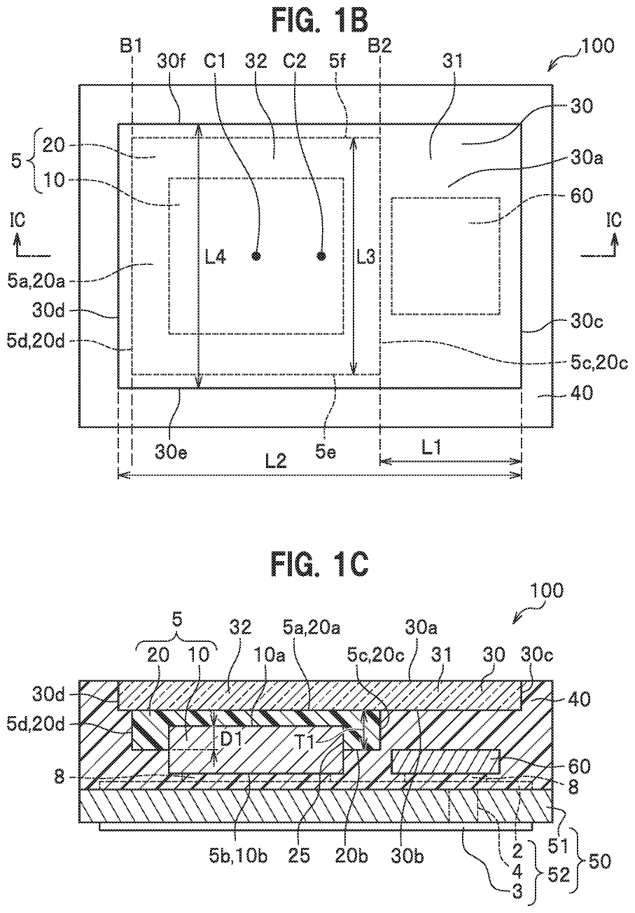

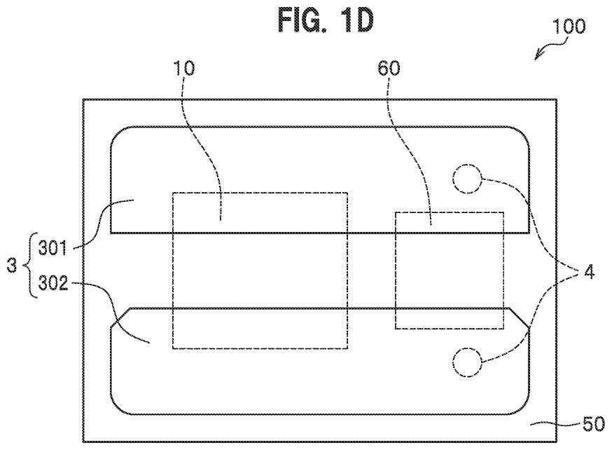

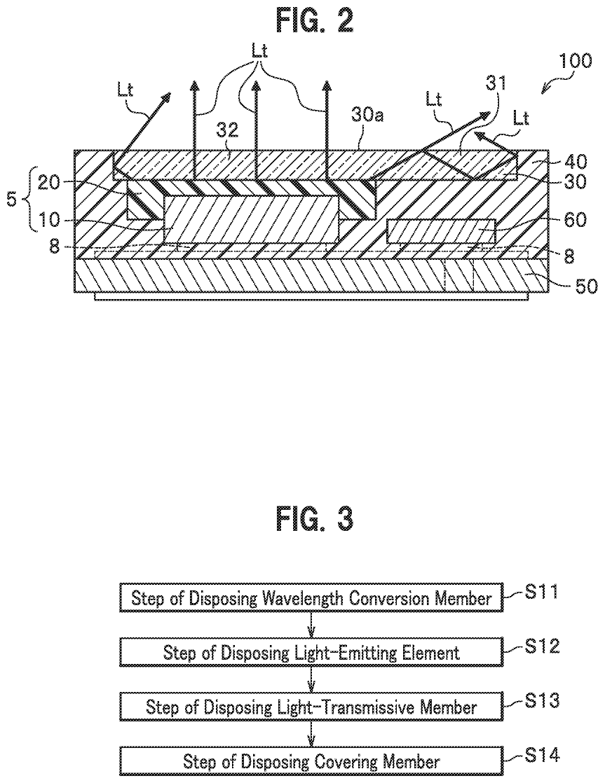

FIG. 1A is a perspective view schematically illustrating a light-emitting device according to a first embodiment. FIG. 1B is a top view schematically illustrating the light-emitting device according to the first embodiment. FIG. 1C is a cross-sectional view schematically illustrating a cross section taken along line IC-IC of FIG. 1B. FIG. 1D is a bottom view schematically illustrating the light-emitting device according to the first embodiment. FIG. 2 is a cross-sectional view schematically illustrating a light path from a light source of the light-emitting device according to the first embodiment.

A light-emitting device 100 includes a light source 5 including a light-emitting element 10 and having a light-emitting surface on an upper surface 5a, a light-transmissive member 30 including a first surface 30a and a second surface 30b located on an opposite side of the first surface 30a and disposed so that the second surface 30b faces the upper surface 5a of the light source 5, and a covering member 40 exposing the first surface 30a of the light-transmissive member 30 and covering lateral surfaces of the light-transmissive member 30 and lateral surfaces of the light source 5. The lateral surfaces of the light source 5 include a first lateral surface 5c continuous with the upper surface 5a and a second lateral surface 5d located on an opposite side of the first lateral surface 5c, and the lateral surfaces of the light-transmissive member 30 include a first lateral surface 30c located on the same side as the first lateral surface 5c of the light source 5 and a second lateral surface 30d located on an opposite side of the first lateral surface 30c.

In the top view, a center C1 of the upper surface 5a of the light source 5 is located closer to the second lateral surface 30d side of the light-transmissive member 30 than a center C2 of the first surface 30a of the light-transmissive member 30, and a length L1 from the first lateral surface 5c of the light source 5 to the first lateral surface 30c of the light-transmissive member 30 is equal to or greater than ¼ of a length L2 from the first lateral surface 30c of the light-transmissive member 30 to the second lateral surface 30d of the light-transmissive member 30.

As an example, a configuration in which the light-emitting device 100 further includes a wiring substrate 50 on which the light source 5 is disposed and an electronic component 60 disposed on the wiring substrate 50 and spaced apart from the light source 5 is described.

Each configuration of the light-emitting device 100 is described below.

### Light Source

The light source 5 includes the light-emitting element 10. The light source 5 can use only the light-emitting element 10. Alternatively, the light source 5 may include another member such as the wavelength conversion member 20 on the light-emitting element 10. In the present embodiment, the light source 5 includes the light-emitting element 10 and the wavelength conversion member 20, an upper surface of the wavelength conversion member 20 is referred to as a first upper surface 20a, a lower surface of the wavelength conversion member 20 is referred to as a first lower surface 20b, an upper surface of the light-emitting element 10 is referred to as a second upper surface 10a, and a lower surface of the light-emitting element 10 is referred to as a second lower surface 10b. The first upper surface 20a of the wavelength conversion member 20 constitutes the upper surface 5a of the light source 5, and the second lower surface 10b of the light-emitting element 10 constitutes the lower surface 5b of the light source 5. A first lateral surface 20c of the wavelength conversion member 20 constitutes the first lateral surface 5c of the light source 5, and a second lateral surface 20d of the wavelength conversion member 20 constitutes the second lateral surface 5d of the light source 5. Note that lateral surfaces of the light-emitting element 10 also constitute a part of the lateral surfaces of the light source 5.

In the top view, the light source 5 may have various shapes such as a circular shape, an elliptical shape, or a polygonal shape such as a quadrangular shape or a hexagonal shape. In particular, in the top view, quadrilateral shapes such as a square shape and a rectangular shape are preferable. In this case, the light source 5 has a rectangular shape in the top view, as an example.

### Light-Emitting Element

The light-emitting element 10 includes the second upper surface 10a, the second lower surface 10b located on an opposite side of the second upper surface 10a, and the lateral surfaces continuous with the second upper surface 10a and the second lower surface 10b.

As the light-emitting element 10, a light-emitting diode can be used. The light-emitting element 10 includes a semiconductor structure and at least a pair of positive and negative element electrodes. The semiconductor structure includes an n-side semiconductor layer, a p-side semiconductor layer, and an active layer interposed between the n-side semiconductor layer and the p-side semiconductor layer. The active layer may have a single quantum well (SQW) structure, or may have a multi quantum well (MQW) structure including a plurality of well layers. The semiconductor structure includes a plurality of semiconductor layers each made of a nitride semiconductor. The nitride semiconductor includes a semiconductor having all compositions in which in a chemical formula of InₓAl_{y}Ga_{1-x-y}N (0≤x, 0≤y, and x+y≤1), composition ratios x and y are changed within respective ranges. The light emission peak wavelength of the active layer can be selected as appropriate according to the purpose. The active layer is configured, for example, so as to be able to emit visible light or ultraviolet light.

The semiconductor structure may include a plurality of light-emitting portions each including the n-side semiconductor layer, the active layer, and the p-side semiconductor layer. When the semiconductor structure includes the plurality of light-emitting portions, the plurality of light-emitting portions may each include well layers having different light emission peak wavelengths or well layers having the same light emission peak wavelength. Note that having the same light emission peak wavelength includes a case in which there is a variation of about a few nm. The combination of the light emission peak wavelengths of the plurality of light-emitting portions can be selected as appropriate. For example, when the semiconductor structure includes two light-emitting portions, combinations of light emitted from each of the light-emitting portions include a combination of blue light and blue light, a combination of green light and green light, a combination of red light and red light, a combination of ultraviolet light and ultraviolet light, a combination of blue light and green light, a combination of blue light and red light, or a combination of green light and red light. For example, when the semiconductor structure includes three light-emitting portions, the combinations of light emitted from each of the light-emitting portions include a combination of blue light, green light, and red light. Each of the light-emitting portions may include one or more well layers having light emission peak wavelengths different from the light emission peak wavelengths of other well layers.

Any shape, size, and the like can be selected for the light-emitting element 10. The light-emitting element 10 may include a support substrate that supports the semiconductor structure. Examples of the support substrate include an insulating substrate made of sapphire, spinel (MgAl₂O₄), and a nitride-based semiconductor substrate made of InN, AlN, GaN, InGaN, AlGaN, or InGaAlN. Preferably, the support substrate uses a light-transmissive material in order to extract light emitted from the light-emitting portions through the support substrate. When the light-emitting element 10 includes the support substrate, the light-emitting element 10 may include a plurality of semiconductor structures on the support substrate.

At least a pair of positive and negative element electrodes may be disposed on the same surface side of the semiconductor structure or may be disposed on different surface sides. The light-emitting element 10 having a desired electrode arrangement can be appropriately selected depending on the form or the like of the wiring substrate 50 used in the light-emitting device 100. The light-emitting element 10 can be disposed on an upper surface wiring 2 of the wiring substrate 50 via a conductive member 8, for example. Eutectic solder, conductive paste such as metal, a bump, or the like can be used for the conductive member 8. Note that regarding the light-emitting element 10 and the upper surface wiring 2, the element electrodes of the light-emitting element 10 and the upper surface wiring 2 may be directly joined without the intervention of the conductive member 8.

### Wavelength Conversion Member

In the light-emitting device 100, the light source 5 includes the wavelength conversion member 20 disposed on the second upper surface 10a of the light-emitting element 10. In this case, the wavelength conversion member 20 has a rectangular shape in the top view, as an example. The wavelength conversion member 20 includes the first upper surface 20a constituting the upper surface 5a of the light source 5, the first lower surface 20b located on the opposite side of the first upper surface 20a, and the lateral surfaces continuous with the first upper surface 20a and the first lower surface 20b. The first lower surface 20b may be a surface substantially parallel to the first upper surface 20a and may have a recessed portion 25 recessed toward the light-emitting element 10. The first lower surface 20b includes the recessed portion 25, and a part of the light-emitting element 10 is disposed in the recessed portion 25. Lateral surfaces of the recessed portion 25 may or may not in contact with a part of the lateral surfaces of the light-emitting element 10. The recessed portion 25 is a portion formed by embedding a part of the light-emitting element 10 in the wavelength conversion member 20 in a manufacturing process. Note that when the wavelength conversion member 20 includes the recessed portion 25, the first lower surface 20b of the wavelength conversion member 20 is assumed to include the bottom surface and the lateral surfaces of the recessed portion 25, the bottom surface and the lateral surfaces defining the recessed portion 25.

By disposing a part of the light-emitting element 10 in the recessed portion 25 of the wavelength conversion member 20, the thickness of the light source 5 including the light-emitting element 10 and the wavelength conversion member 20 can be reduced in the wavelength conversion member 20. Thus, light emitted from the light source 5 in a lateral direction is reduced, and the light extraction efficiency from the upper surface is improved.

The first lower surface 20b of the wavelength conversion member 20 has a larger area than the second upper surface 10a of the light-emitting element 10. Specifically, in the top view, the wavelength conversion member 20 has a size so that an outer edge of the wavelength conversion member 20 is located outside an outer edge of the light-emitting element 10. The lateral surface of the wavelength conversion member 20 may be any of a surface perpendicular to the first upper surface 20a and/or the first lower surface 20b, an inclined surface, a curved surface, and the like, and may include a partially perpendicular region, an inclined region, or a curved region.

Preferably, a thickness T1 of the wavelength conversion member 20 is 30 μm or more from the viewpoint of improving wavelength conversion efficiency and mechanical strength and is 100 μm or less from the viewpoint of reducing the light-emitting device 100 in size. Note that the thickness of the wavelength conversion member 20 is a length in a direction from the first lower surface 20b of the wavelength conversion member 20 toward the first upper surface 20a of the wavelength conversion member 20. When the wavelength conversion member 20 includes the recessed portion 25, the thickness of the wavelength conversion member 20 refers to a thickness of a portion where the recessed portion 25 is not formed.

A depth D1 of the recessed portion 25 of the wavelength conversion member 20 is preferably ⅕ or more of a thickness of the light-emitting element 10 from the viewpoint of adhesion to the light-emitting element 10. From the viewpoint of wavelength conversion efficiency, a thickness from the bottom of the recessed portion 25 to the first upper surface 20a (that is, the difference between T1 and D1) is preferably 20 μm or more.

The wavelength conversion member 20 includes, for example, phosphors that wavelength-convert first light emitted from the light-emitting element 10 into second light. The light emission peak wavelength of the first light is in a range from 420 nm to 460 nm, for example. The light emission peak wavelength of the second light is in a range from 500 nm to 600 nm, for example. The phosphor concentration of the wavelength conversion member 20 is preferably in a range from 25 mass % to 70 mass %, for example. The phosphor concentration refers to the proportion of the phosphor in the wavelength conversion member 20 including the phosphor.

Examples of the wavelength conversion member 20 include a sintered compact of a phosphor, a light-transmissive resin, glass, or ceramics, containing phosphor powder. As the light-transmissive resin, a resin containing one or more of a silicone resin, a modified silicone resin, an epoxy resin, a modified epoxy resin, an acrylic resin, a phenol resin, and a polyimide resin can be used, for example.

The phosphor can use an yttrium aluminum garnet-based phosphor (for example, (Y,Gd)₃(Al,Ga)₅O₁₂:Ce), a lutetium aluminum garnet-based phosphor (for example, Lu₃(Al,Ga)₅O₁₂:Ce), a terbium aluminum garnet-based phosphor (for example, Tb₃(Al,Ga)₅O₁₂:Ce), a CCA-based phosphor (for example, Ca₁₀(PO₄)₆Cl₂:Eu), an SAE-based phosphor (for example, Sr₄Al₁₄O₂₅:Eu), a chlorosilicate-based phosphor (for example, CasMgSi₄O₁₆Cl₂:Eu), a silicate-based phosphor (for example, (Ba,Sr,Ca,Mg)₂SiO₄:Eu), an oxynitride phosphor such as a β-sialon-based phosphor (for example, (Si,Al)₃(O,N)₄:Eu) or an α-sialon-based phosphor (for example, Ca(Si,Al)₁₂(O,N)₁₆:Eu), a nitride-based phosphor such as an LSN-based phosphor (for example, (La, Y)₃Si₆N₁₁:Ce), a BSESN-based phosphor (for example, (Ba,Sr)₂Si₅N₈:Eu), an SLA-based phosphor (for example, SrLiAl₃N₄:Eu), a CASN-based phosphor (for example, CaAlSiN₃:Eu), or an SCASN-based phosphor (for example, (Sr,Ca)AlSiN₃:Eu), a fluoride phosphor such as a KSF-based phosphor (for example, K₂SiF₆:Mn), a KSAF-based phosphor (for example, K₂(Si₁₋ₓAlₓ)F₆₋ₓ:Mn, where x satisfies 0<x<1), or an MGF-based phosphor (for example, 3.5MgO·0.5MgF₂·GeO₂:Mn), a quantum dot having a perovskite structure (for example, (Cs,FM,MA)(Pb,Sn)(F,Cl,Br,I)₃, where FA and MA represent formamidinium and methylammonium, respectively), a group II-VI quantum dot (for example, CdSe), a group III-V quantum dot (for example, InP), a quantum dot having a chalcopyrite structure (for example, (Ag,Cu)(In,Ga)(S,Se)₂), or the like.

### Light-Transmissive Member

The light-emitting device 100 includes the light-transmissive member 30. The light-transmissive member 30 includes the first surface 30a and the second surface 30b located on the opposite side of the first surface 30a. The first surface 30a of the light-transmissive member 30 can be used as a light-emitting surface of the light-emitting device 100. In the light-emitting device 100, the light-transmissive member 30 is disposed so that the second surface 30b faces the upper surface 5a of the light source 5. In the top view, the light-transmissive member 30 may have various shapes such as a circular shape, an elliptical shape, or a polygonal shape such as a quadrangular shape or a hexagonal shape. In particular, quadrilateral shapes such as a square shape and a rectangular shape are preferable. In this case, the light-transmissive member 30 has a rectangular shape in the top view, as an example.

The light-transmissive member 30 includes lateral surfaces continuous with the first surface 30a and the second surface 30b. The lateral surfaces of the light-transmissive member 30 include the first lateral surface 30c located on the same side as the first lateral surface 5c of the light source 5 and the second lateral surface 30d located on the opposite side of the first lateral surface 30c.

The second surface 30b of the light-transmissive member 30 has a larger area than the first upper surface 20a of the wavelength conversion member 20. That is, the light-transmissive member 30 having a size so that an outer edge of the light-transmissive member 30 located outside the outer edge of the wavelength conversion member 20 in the top view is disposed. The lateral surface of the light-transmissive member 30 may be any of a surface perpendicular to the upper surface and/or the lower surface, an inclined surface, a curved surface, and the like. Note that the light-transmissive member 30 may have an uneven structure on part or the entire surface of the light-transmissive member 30.

Preferably, a thickness of the light-transmissive member 30 is 30 μm or more from the viewpoint of improving mechanical strength, is 300 μm or less from the viewpoint of reducing the light-emitting device 100 in size, and is in a range from 100 μm to 200 μm.

The light-transmissive member 30 is made of, for example, a light-transmissive material such as a resin, glass, or an inorganic material molded into a plate shape. Examples of the glass that can be used include borosilicate glass and quartz glass, and examples of the resin that can be used include a silicone resin, an epoxy resin, and an acrylic resin. In particular, glass is preferably used for the light-transmissive member in consideration of resistance to degradation by light, mechanical strength, and the like. Note that the light-transmissive member 30 may contain a light diffusion material. When the light-transmissive member 30 contains a light diffusion material, uneven chromaticity and uneven brightness can be inhibited. Examples of the light diffusion material that can be used include titanium oxide, barium titanate, aluminum oxide, and silicon oxide.

The lateral surfaces of the light source 5 include the first lateral surface 5c continuous with the upper surface 5a of the light source 5 and the second lateral surface 5d located on the opposite side of the first lateral surface 5c. The lateral surfaces of the light-transmissive member 30 include the first lateral surface 30c located on the same side as the first lateral surface 5c of the light source 5 and the second lateral surface 30d located on the opposite side of the first lateral surface 30c.

In the light-emitting device 100, the center C1 of the upper surface 5a of the light source 5 is located closer to the second lateral surface 30d side of the light-transmissive member 30 than the center C2 of the first surface 30a of the light-transmissive member 30 in the top view. In the light-emitting device 100, the length L1 from the first lateral surface 5c of the light source 5 to the first lateral surface 30c of the light-transmissive member 30 is equal to or greater than ¼ of the length L2 from the first lateral surface 30c of the light-transmissive member 30 to the second lateral surface 30d of the light-transmissive member 30 in the top view. The length L1 is the shortest distance from the first lateral surface 5c of the light source 5 to the first lateral surface 30c of the light-transmissive member 30 in the top view, and the length L2 is the shortest distance from the first lateral surface 30c of the light-transmissive member 30 to the second lateral surface 30d of the light-transmissive member 30 in the top view.

That is, in the top view of the light-transmissive member 30, an area from a straight line in contact with the first lateral surface 5c of the light source 5 (that is, a line B2 in FIG. 1B) to the first lateral surface 30c of the light-transmissive member 30 is larger than an area from a straight line in contact with the second lateral surface 5d of the light source 5 (that is, a line B1 in FIG. 1B) to the second lateral surface 30d of the light-transmissive member 30. Thus, the light-transmissive member 30 includes a first region 31 on the first lateral surface 30c side of the light-transmissive member 30 as a region not overlapping the light source 5 in the top view. The first region 31 has a larger area than a region not overlapping the light source 5 on the second lateral surface 30d side of the light-transmissive member 30 in the top view. In FIG. 1B, the first region 31 is a region from the line B2 in contact with the first lateral surface 20c of the wavelength conversion member 20 to the first lateral surface 30c of the light-transmissive member 30. Note that in the light-emitting device 100, the second lateral surface 30d of the light-transmissive member 30 and the second lateral surface 5d of the light source 5 may coincide with each other in the top view.

In the light-emitting device 100, the light-transmissive member 30 includes the first region 31, so that when the first surface 30a of the light-transmissive member 30 is used as the light-emitting surface of the light-emitting device 100, the brightness of the first region 31 on the light-emitting surface of the light-emitting device 100 can be made less than the brightness of a region (hereinafter, referred to as a second region 32) overlapping the light source 5 on the light-emitting surface in the top view. Since the light-emitting element 10 is disposed below the second region 32, light emitted from the second region 32 has higher brightness than light emitted from the first region 31. Thus, the light-emitting device 100 can include the first region 31 and the second region 32 having a brightness difference on the light-emitting surface. Therefore, for example, when the light-emitting device 100 is used as an on-vehicle headlight, a high brightness region can be provided in a desired region of an irradiation region. That is, a desired light distribution can be easily obtained without using complicated optical design of reflectors, lenses, and the like, so that the size of the headlight can be reduced, and the design of the headlight can be further enhanced.

The length L1 from the first lateral surface 5c of the light source 5 to the first lateral surface 30c of the light-transmissive member 30 is preferably equal to or greater than ¼ of the length L2 from the first lateral surface 30c of the light-transmissive member 30 to the second lateral surface 30d of the light-transmissive member 30, more preferably equal to or greater than about ⅓. Thus, the first region 31 and the second region 32 that emits light with higher brightness than light emitted from the first region 31 can be disposed on the light-emitting surface. Note that from the viewpoint of reducing the size of the light-emitting device 100, the length L1 from the first lateral surface 5c of the light source 5 to the first lateral surface 30c of the light-transmissive member 30 is preferably equal to or less than ¾ of the length L2 from the first lateral surface 30c of the light-transmissive member 30 to the second lateral surface 30d of the light-transmissive member 30, more preferably equal to or less than about ⅔.

A length L3 from a third lateral surface 5e of the light source 5 to a fourth lateral surface 5f of the light source 5 can be set in a range from 80% to 100% of a length L4 from a third lateral surface 30e of the light-transmissive member 30 to a fourth lateral surface 30f of the light-transmissive member 30. The length L3 is the shortest distance from the third lateral surface 5e of the light source 5 to the fourth lateral surface 5f of the light source 5 in the top view, and the length L4 is the shortest distance from the third lateral surface 30e of the light-transmissive member 30 to the fourth lateral surface 30f of the light-transmissive member 30 in the top view. Note that the length L3 from the third lateral surface 5e of the light source 5 to the fourth lateral surface 5f of the light source 5 can be appropriately set in accordance with a desired light distribution.

As an example, the light-emitting device 100 can be used as a low beam light source for a headlight of a vehicle. In this case, the light-emitting device 100 is disposed so that light emitted from the second region 32 (that is, a high brightness region) illuminates an upper side in a vertical direction of a light distribution pattern of the headlight and light emitted from first region 31 (that is, a low brightness region) illuminates a lower side in the vertical direction of the light distribution pattern of the headlight. Thus, a road surface in the vicinity of the vehicle in an irradiation region of the low beam headlight is less likely to be illuminated more brightly than necessary, and the occurrence of glare due to road surface reflection can be reduced. In this case, for example, when the planar shape of the light source 5 is a rectangle having the above-described length L3 as a long side, the light distribution pattern of the headlight can be illuminated more brightly in a left-right direction.

### Wiring Substrate

In the light-emitting device 100, the light-emitting element 10 can be disposed on the wiring substrate 50. The wiring substrate 50 includes a base body 51 and a plurality of wirings 52 serving as electrodes of the light-emitting device 100.

For the base body 51, any material known in the art can be used as the base body that is included in the wiring substrate for supporting electronic components such as the light-emitting element. For example, an insulating material such as glass epoxy, a resin, or a ceramic, a semiconductor material such as silicon, or a conductive material such as copper may be used. In particular, a ceramic, which has high heat resistance and light resistance, can be preferably used. Examples of a ceramic include aluminum oxide, aluminum nitride, silicon nitride, LTCC, and the like. In addition, a composite material of such an insulating material, a semiconductor material, and a conductive material may also be used. When the base body 51 is formed using a semiconductor material or a conductive material, the wiring line 52 can be disposed on an upper surface and a lower surface of the base body 51 via an insulating layer.

The wiring 52 includes at least the upper surface wiring 2 disposed on the upper surface of the substrate and connected to the light-emitting element 10. The wiring 52 further includes a lower surface wiring 3 (for example, an anode terminal 301 and a cathode terminal 302) which is an external connection terminal disposed on an upper surface and a lower surface opposite to the upper surface and electrically connected to an external power supply, and an inner layer wiring electrically connecting the upper surface wiring 2 and the lower surface wiring 3. The inner layer wiring includes, for example, a via 4 penetrating the base body 51. Note that the wiring substrate 50 may include a lateral surface wiring disposed on a lateral surface as a wiring for electrically connecting the upper surface wiring 2 and the lower surface wiring 3.

Examples of the material for the wiring line 52 include metals such as Fe, Cu, Ni, Al, Ag, Au, Pt, Ti, W, and Pd, and alloys containing at least one kind of these metals.

### Electronic Component

The electronic component 60 is, for example, a protective element. The protective element is a Zener diode, for example. The electronic component 60 is disposed on the upper surface wiring 2 of the wiring substrate 50 by the conductive member 8, for example. Note that the light-emitting device 100 may not include the electronic component 60.

### Covering Member

The light-emitting device 100 can include the covering member 40 covering the light source 5 and the light-transmissive member 30.

The covering member 40 exposes the first surface 30a of the light-transmissive member 30 and covers the lateral surfaces of the light-transmissive member 30 and the lateral surfaces of the light source 5. When the light-emitting device 100 includes the electronic component 60, the covering member 40 preferably covers the electronic component 60. When the light-emitting element 10 is disposed on the wiring substrate 50, the covering member 40 preferably covers the upper surface wiring 2 of the wiring substrate 50.

The covering member 40 preferably has a light-shielding property, specifically, preferably has a light-reflecting property. Preferably, the covering member 40 is formed using an insulating material. For example, a thermosetting resin, a thermoplastic resin, or the like can be used for the covering member 40. Specifically, an example of the covering member 40 includes a resin containing particles of a light reflective material. Examples of the resin include a resin containing at least one of a silicone resin, a modified silicone resin, an epoxy resin, a modified epoxy resin, an acrylic resin, a phenol resin, a bismaleimide triazine resin, and a polyphthalamide resin, and a hybrid resin thereof. Among these materials, it is preferable to use a resin containing, as a base polymer, a silicone resin, which exhibits a good heat resistance property and electrically insulating property and has flexibility. Examples of the light reflective material include titanium oxide, silicon oxide, zirconium oxide, aluminum oxide, magnesium oxide, calcium carbonate, calcium hydroxide, calcium silicate, zinc oxide, barium titanate, potassium titanate, aluminum nitride, boron nitride, and mullite, and a combination thereof. Among these materials, titanium oxide is preferable because it is relatively stable with respect to moisture or the like and has a high refractive index.

The concentration of the light reflective material of the covering member 40 is preferably in a range from 60 mass % to 70 mass %. The concentration of the light reflective material indicates the proportion of the light reflective material in the covering member 40 including the light reflective material.

The reflectance of the covering member 40 is preferably in a range from 1% to 95%, for example. The reflectance means the reflectance at the light emission peak wavelength of light emitted from the light-emitting element 10.

The total light transmittance of the covering member 40 is preferably in a range from 1% to 35%, for example. The total light transmittance is the proportion of the amount of light transmitted through a targeted object to the amount of light incident on the targeted object. For example, the total light transmittance refers to a total light transmittance measured in compliance with Japan industrial standard JIS K 7375:2008.

### Operation of Light-Emitting Device

When power is supplied to the light-emitting device 100 from an external power supply, the light-emitting element 10 emits light. At least a part of the first light emitted from the light-emitting element 10 is wavelength-converted to the second light by the phosphor included in the wavelength conversion member 20. The second light is mixed with the first light that has not been wavelength-converted to the second light. The mixed light is emitted to the outside as white light, for example. At this time, as described above, the light-transmissive member 30 includes the first region 31. Since the first region 31 is a region not overlapping the light source 5 in the top view, the amount of light emitted from the first region 31 is less than the amount of light emitted from the second region 32 below which the light-emitting element 10 is disposed. Therefore, the brightness of the second region 32 is relatively higher than the brightness of the first region 31 on the light-emitting surface of the light-emitting device 100. Thus, the light-emitting device 100 having a high brightness region on the light-emitting surface can be obtained. In this manner, the light-emitting device 100 can include a high brightness region in the irradiation region of light emitted from a light-emitting region. Note that the light-emitting region is the light-emitting surface of the light-emitting device 100, and the light-emitting surface of the light-emitting device 100 is the first surface 30a of the light-transmissive member 30.

With reference to FIG. 2, the brightness difference between the first region 31 and the second region 32 on the light-emitting surface of the light-emitting device 100 is specifically described below. The description is be made with reference to FIGS. 1B and 1C as necessary. Note that FIG. 2 schematically illustrates only a part of the light path for the sake of simplification of the description. While the travelling direction of the actual light changes as necessary between members and inside each member through refraction, scattering, and the like, the illustration may be omitted for the sake of simplification.

A large part of light Lt emitted from the light source 5 is emitted from the first surface 30a of the light-transmissive member 30 on the wavelength conversion member 20 side. On the other hand, since the first region 31 of the light-transmissive member 30 is spaced from the light source 5 in the top view, the amount of light Lt emitted from the first surface 30a of the light-transmissive member 30 in the first region 31 is less than the amount of light Lt emitted from the second region 32 below which the light-emitting element 10 is located. Thus, the amount of light emitted from the first region 31 side decreases. Therefore, the brightness on the first region 31 side of the light-emitting surface of the light-emitting device 100 is less, and the brightness on the wavelength conversion member 20 side of the light-emitting surface is relatively high.

### Method for Manufacturing Light-Emitting Device

A method for manufacturing the light-emitting device 100 is described below. Note that the materials, arrangement, and the like of the members are as in the description of the light-emitting device 100, and thus descriptions thereof will be omitted as appropriate. The number of light-emitting elements and the size of the light source, and the size of the light-transmissive member are illustrated in an easy-to-illustrative manner and are therefore not limited to the illustration. The description is be made with reference to FIGS. 1A to 1D as necessary.

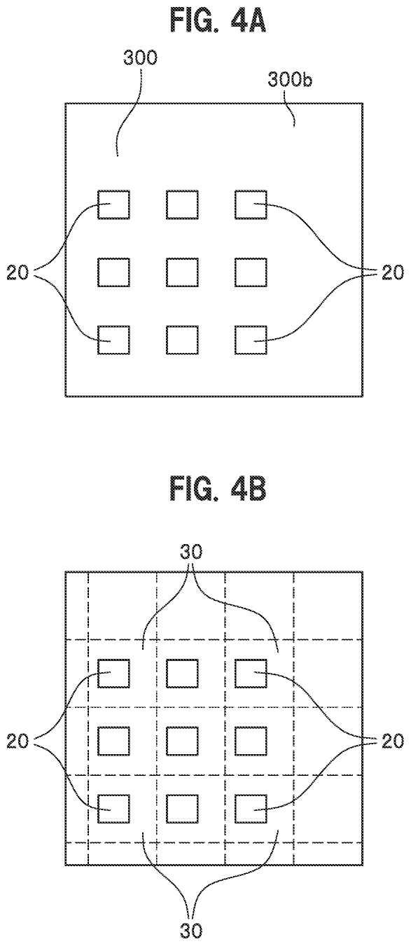

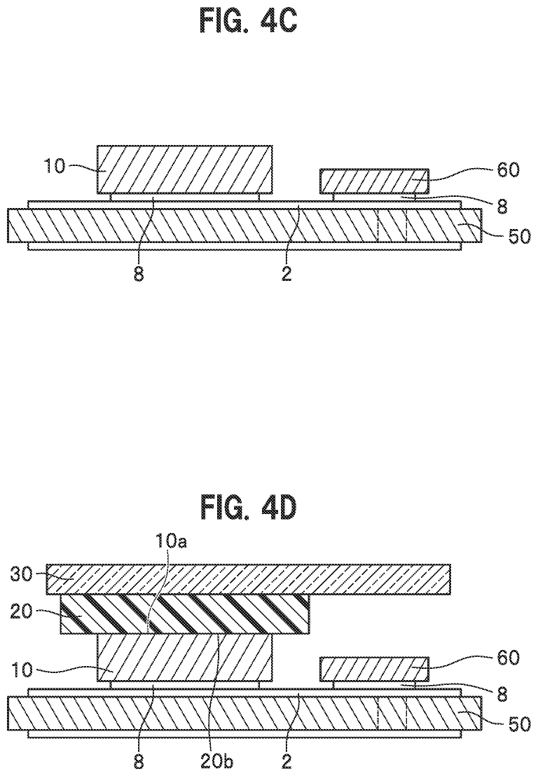

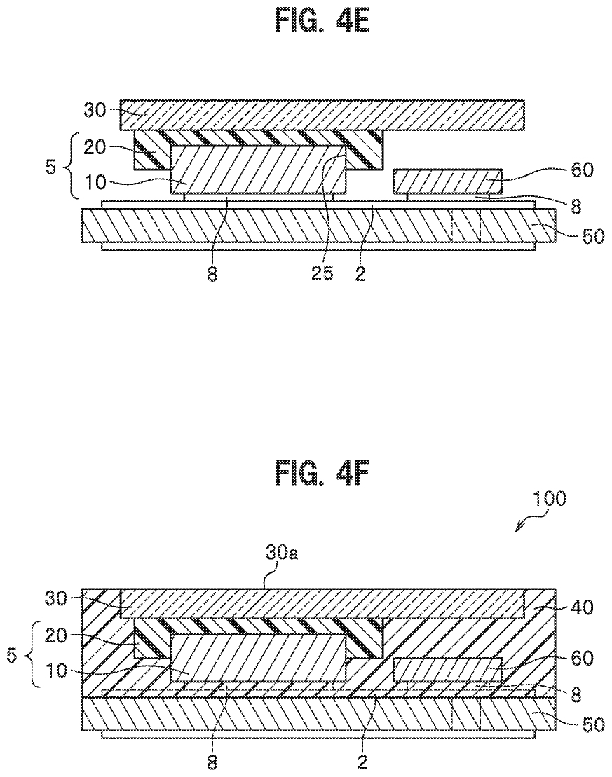

FIG. 3 is a flowchart of a method for manufacturing the light-emitting device according to the first embodiment. FIGS. 4A and 4B are top views schematically illustrating the method for manufacturing the light-emitting device according to the first embodiment. FIGS. 4C to 4F are cross-sectional views schematically illustrating the method for manufacturing the light-emitting device according to the first embodiment.

The method for manufacturing the light-emitting device 100 includes a step of disposing the light source 5 including the light-emitting element 10 and having a light-emitting surface on the upper surface 5a on the second surface 30b of the light-transmissive member 30 having the first surface 30a and the second surface 30b located on the opposite side of the first surface 30a so that the upper surface 5a of the light source 5 faces the second surface 30b, and a step of disposing the covering member 40 so as to expose the first surface 30a of the light-transmissive member 30 and cover the lateral surfaces of the light-transmissive member 30 and the lateral surfaces of the light source 5. The lateral surfaces of the light source 5 include the first lateral surface 5c continuous with the upper surface 5a and the second lateral surface 5d located on the opposite side of the first lateral surface 5c. The lateral surfaces of the light-transmissive member 30 include the first lateral surface 30c located on the same side as the first lateral surface 5c of the light source 5 and the second lateral surface 30d located on the opposite side of the first lateral surface 30c.

In the step of disposing the light source 5, in the top view, the light source 5 are disposed so that the center C1 of the upper surface 5a of the light source 5 is located closer to the second lateral surface 30d side of the light-transmissive member 30 than the center C2 of the first surface 30a of the light-transmissive member 30, and the length L1 from the first lateral surface 5c of the light source 5 to the first lateral surface 30c of the light-transmissive member 30 is equal to or greater than ¼ of the length L2 from the first lateral surface 30c of the light-transmissive member 30 to the second lateral surface 30d of the light-transmissive member 30.

The method for manufacturing the light-emitting device 100 may further include, in the step of disposing the light source 5, a step of disposing the wavelength conversion member 20 including the first upper surface 20a and the first lower surface 20b located on the opposite side of the first upper surface 20a on the second surface 30b of the light-transmissive member 30 having the first surface 30a and the second surface 30b located on the opposite side of the first surface 30a so that the first upper surface 20a of the wavelength conversion member 20 faces the second surface 30b, and a step of joining the light-emitting element 10 and the wavelength conversion member 20 so that the second upper surface 10a of the light-emitting element 10 including the second upper surface 10a and the second lower surface 10b located on the opposite side of the second upper surface 10a faces the first lower surface 20b of the wavelength conversion member 20.

The method for manufacturing the light-emitting device 100 may further include a step of disposing the light-emitting element 10 on the wiring substrate 50 before the step of disposing the covering member 40.

The method for manufacturing the light-emitting device 100 is described as including a step S11 of disposing the wavelength conversion member, a step S12 of disposing the light-emitting element, a step S13 of disposing the light-transmissive member, and a step S14 of disposing the covering member.

### Step of Disposing Wavelength Conversion Member

The step S11 of disposing the wavelength conversion member is a step of disposing the wavelength conversion member 20 so that the first upper surface 20a of the wavelength conversion member 20 faces the second surface 30b of the light-transmissive member 30 as illustrated in FIGS. 4A and 4B.

In the step S11 of disposing the wavelength conversion member, a plurality of uncured or semi-cured resins constituting the wavelength conversion members 20 are first disposed on a second surface 300b of a light-transmissive member 300 having a flat plate shape at predetermined intervals so as to have a predetermined size and shape. The resins can be disposed by printing or potting, for example. Subsequently, the light-transmissive member 300 is divided and singulated at a desired position, and the light-transmissive member 30 including the wavelength conversion member 20 is obtained. The singulation can be performed by cutting the light-transmissive member 300 with laser irradiation or a tool such as a blade.

In the step S11 of disposing the wavelength conversion member, in the top view, the position where the wavelength conversion member 20 is disposed and the position where the light-transmissive member 300 is divided are appropriately adjusted so that the center of the first upper surface 20a of the wavelength conversion member 20 (that is, the center C1 of the upper surface 5a of the light source 5) is located closer to the second lateral surface 30d side of the light-transmissive member 30 than the center C2 of the first surface 30a of the light-transmissive member 30, and the length L1 from the first lateral surface 20c of the wavelength conversion member 20 (that is the first lateral surface 5c of the light source 5) to the first lateral surface 30c of the light-transmissive member 30 is equal to or greater than ¼ of the length L2 from the first lateral surface 30c of the light-transmissive member 30 to the second lateral surface 30d of the light-transmissive member 30.

In the above description, the light-transmissive member 300 having a flat plate shape and including a plurality of regions to be the light-transmissive members 30 after the singulation is prepared, is divided after the wavelength conversion member 20 is disposed, and the plurality of light-transmissive members 30 on which the wavelength conversion member 20 is disposed are prepared at a time; however, the light-transmissive members 30 on which the wavelength conversion member 20 is disposed may be individually disposed.

### Step of Disposing Light-Emitting Element

The step S12 of disposing the light-emitting element is a step of disposing the light-emitting element 10 on the wiring substrate 50 as illustrated in FIG. 4C.

In the step S12 of disposing the light-emitting element, the light-emitting element 10 is disposed on the upper surface wiring 2 via the conductive member 8. Note that regarding the light-emitting element 10 and the upper surface wiring 2, the element electrodes of the light-emitting element 10 and the upper surface wiring 2 may be directly joined without the intervention of the conductive member 8. When the light-emitting device 100 includes the electronic component 60, in the step S12 of disposing the light-emitting element, the electronic component 60 is disposed on the wiring substrate 50 before or after the light-emitting element 10 is disposed on the wiring substrate 50. Note that the electronic component 60 may be disposed at any timing before the step S14 of disposing the covering member.

### Step of Disposing Light-Transmissive Member

The step S13 of disposing the light-transmissive member is a step of disposing the light-transmissive member 30 so that the second upper surface 10a of the light-emitting element 10 faces the first lower surface 20b of the wavelength conversion member 20, as illustrated in FIGS. 4D and 4E. In the step S13 of disposing the light-transmissive member, the light source 5 to which the light-transmissive member 30 is joined is manufactured.

In the step S13 of disposing the light-transmissive member, the second upper surface 10a of the light-emitting element 10 may be disposed on the first lower surface 20b of the wavelength conversion member 20 via a light-transmissive adhesive or the like, or the light-emitting element 10 may be disposed so that a part of the light-emitting element 10 is embedded in the first lower surface 20b of the wavelength conversion member 20 as in the present embodiment. When a part of the light-emitting element 10 is embedded in the first lower surface 20b of the wavelength conversion member 20, the wavelength conversion member 20 preferably includes a resin. When the wavelength conversion member 20 includes a resin, the resin constituting the wavelength conversion member 20 is preferably in an uncured or semi-cured state in the step of disposing the light-transmissive member. The embedding of the light-emitting element 10 may be performed, for example, by applying pressure from the light-transmissive member 30 side to which the wavelength conversion member 20 is joined, or by applying pressure from the light-emitting element 10 side. Subsequently, the uncured or semi-cured resin constituting the wavelength conversion member 20 is cured to form the wavelength conversion member 20 including the recessed portion 25.

By disposing the light-emitting element 10 so that a part of the light-emitting element 10 is embedded in the first lower surface 20b of the wavelength conversion member 20, the light-emitting element 10 and the wavelength conversion member 20 can be joined to each other without using an adhesive member. In the present embodiment, the light-transmissive member is disposed so that the center C1 of the upper surface 5a of the light source 5, that is, the center of the first upper surface 20a of the wavelength conversion member 20, is located closer to the second lateral surface 30d side of the light-transmissive member 30 than the center C2 of the first surface 30a of the light-transmissive member 30 in the top view. In this case, the light-emitting element 10 is disposed so that a part of the light-emitting element 10 is embedded in the first lower surface 20b of the wavelength conversion member 20 (that is, a part of the light-emitting element 10 is disposed in the recessed portion 25), so that the light-transmissive member 30 can be suppressed from being inclined by its own weight so that the first region 31 side approaches the wiring substrate 50 side.

### Step of Disposing Covering Member

The step S14 of disposing the covering member is a step of disposing the covering member 40 so as to expose the first surface 30a of the light-transmissive member 30 and cover the lateral surfaces of the light-transmissive member 30 and the lateral surfaces of the light source 5 (that is, the lateral surfaces of the wavelength conversion member 20 and the light-emitting element 10), as illustrated in FIG. 4F. Moreover, the covering member 40 may also be disposed to cover the upper surface and the lateral surfaces of the electronic component 60 and the upper surface of the wiring substrate 50. In the step S14 of disposing the covering member, an uncured resin constituting the covering member 40 is disposed on the wiring substrate 50 so as to expose the first surface 30a of the light-transmissive member 30 and cover the lateral surfaces of the light-transmissive member 30 and the lateral surfaces of the light source 5. The resin can be disposed by potting, for example. Furthermore, the resin can also be disposed by compression molding, transfer molding, or the like. Subsequently, the resin is cured to form the covering member 40. Note that the upper surface of the formed covering member 40 may be cut to adjust the height or may be flattened, as necessary.

Note that in the method for manufacturing the light-emitting device 100, a plurality of the light-emitting devices 100 may be manufactured simultaneously by using a single wiring substrate including a plurality of continuous regions each of which becomes the wiring substrate 50 of the light-emitting device 100 after singulation, or the light-emitting devices 100 may be manufactured individually. When the plurality of the light-emitting devices 100 are simultaneously manufactured, the light-emitting devices 100 are formed by performing the singulation after the step S14 of disposing the covering member.

Other embodiments are described below. Note that the description is made with reference to FIGS. 1A to 1D as necessary, and the description of the components described above is omitted as necessary. Note that light-emitting devices according to other embodiments to be described below can each also include a high brightness region on a light-emitting surface.

### Second Embodiment

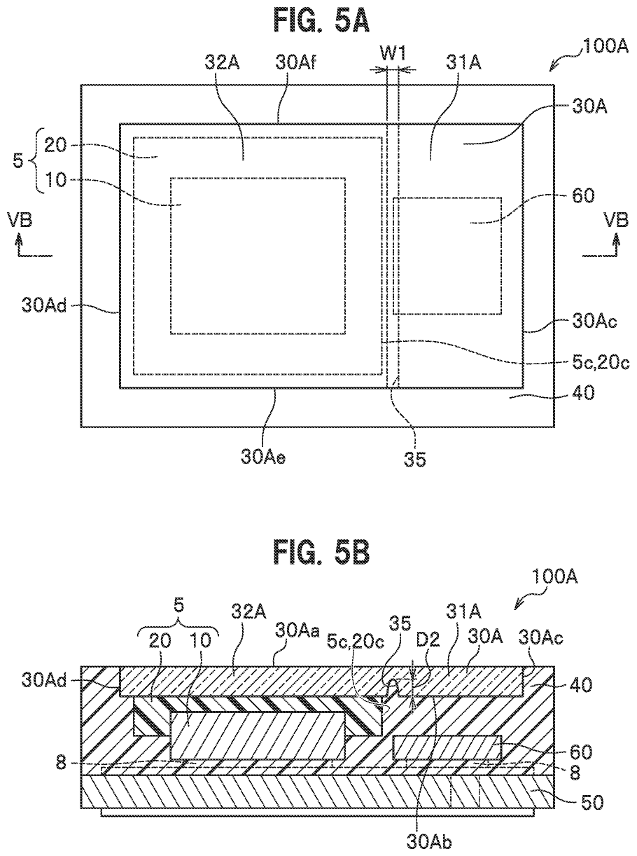

FIG. 5A is a top view schematically illustrating a light-emitting device according to a second embodiment. FIG. 5B is a cross-sectional view schematically illustrating a cross section taken along line VB-VB of FIG. 5A.

The configuration of a light-emitting device 100A is different from the configuration of the light-emitting device 100 of the first embodiment in that a second surface 30Ab of a light-transmissive member 30A includes a groove 35 between a first lateral surface 30Ac and a second lateral surface 30Ad of the light-transmissive member 30A and the light source 5 is disposed between the groove 35 and the second lateral surface 30Ad of the light-transmissive member 30A.

In the light-emitting device 100A, as illustrated in FIGS. 5A and 5B, the groove 35 is preferably a groove that divides the second surface 30Ab of the light-transmissive member 30A into two regions spaced apart from each other. The groove 35 is spaced apart from the first lateral surface 5c of the light source 5 (that is, the first lateral surface 20c of the wavelength conversion member 20 constituting the light source 5) and disposed along the first lateral surface 5c of the light source 5. The groove 35 is continuous from a third lateral surface 30Ae of the light-transmissive member 30A to a fourth lateral surface 30Af of the light-transmissive member 30A. The covering member 40 is disposed in the groove 35.

In the light-emitting device 100A, since the light-transmissive member 30A includes the groove 35, a part of light emitted from the light source 5 and propagating through the light-transmissive member 30A is reflected by the groove 35 and/or the covering member 40 disposed in the groove 35 and is emitted from a second region 32A side, as will be described below. This increases the amount of light emitted from the second region 32A on a light-emitting surface of the light-emitting device 100A. Therefore, the brightness of the light-emitting surface on the light source 5 side is relatively high. Thus, the brightness difference between a first region 31A and the second region 32A on the light-emitting surface can be further increased.

The groove 35 is formed on the second surface 300b of the light-transmissive member 300 having a flat plate shape, for example, after the step S11 of disposing the wavelength conversion member. Alternatively, the groove 35 may be formed after the light-transmissive member 300 is singulated and before the step S13 of disposing the light-transmissive member. The groove 35 can be formed by removing a part of the light-transmissive member by laser irradiation or a tool such as a blade, for example.

A depth D2 of the groove 35 can be set in a range from ⅕ to ½ of a thickness of the light-transmissive member 30A, for example. A width W1 of the groove 35 (that is, the maximum length in the direction from the first lateral surface 30Ac and the second lateral surface 30Ad) is in a range from ½ to 1/1 of a depth D1 of a groove, for example. Note that the depth D2 and the width W1 of the groove 35 may be a substantially constant depth D2 and a substantially constant width W1 over the entire region or may have partially different depths D2 and widths W1.

### Third Embodiment

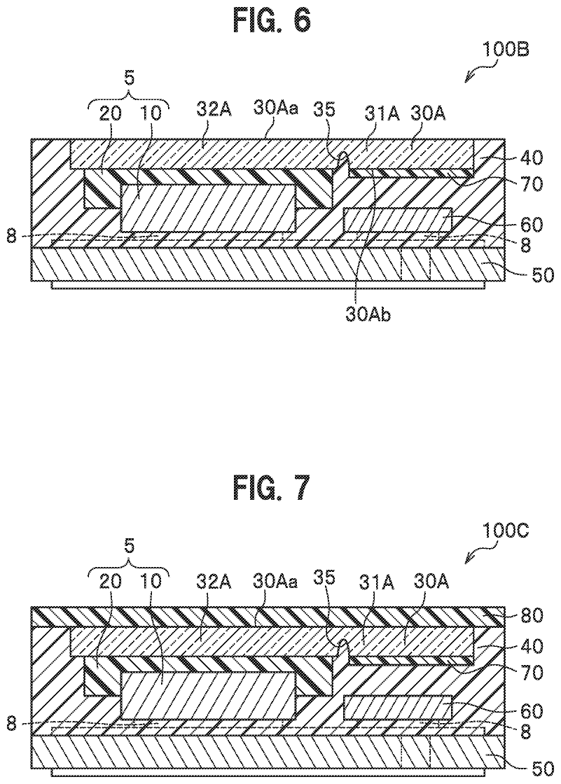

FIG. 6 is a cross-sectional view schematically illustrating a light-emitting device according to a third embodiment.

The configuration of a light-emitting device 100B is different from the configuration of the light-emitting device 100A of the second embodiment in that the light-emitting device 100B includes a light absorbing member 70 spaced apart from the light source 5 and disposed on the second surface 30Ab of the light-transmissive member 30A. The light absorbing member 70 has a light-shielding property and a reflectance preferably less than the covering member 40. Specifically, the light absorbing member 70 preferably has a light absorption property.

As illustrated in FIG. 6, the light absorbing member 70 is disposed in the first region 31A on the second surface 30Ab of the light-transmissive member 30A. The light absorbing member 70 is preferably spaced apart from the light source 5. Moreover, in the present embodiment, as illustrated in FIG. 6, the light-transmissive member 30A preferably includes the groove 35. Note that when the light-transmissive member 30A includes the groove 35, the light absorbing member 70 is preferably not disposed in the groove 35. Thus, absorption of light emitted from the second region 32A by the light absorbing member 70 can be reduced.

Since the light-emitting device 100B includes the light absorbing member 70, a part of light emitted from the light source 5 and guided to the first region 31A side of the light-transmissive member 30A is absorbed by the light absorbing member 70. Therefore, the brightness of the first region 31A on a light-emitting surface of the light-emitting device 100B can be made relatively less than the brightness of the second region 32A. Thus, the brightness difference between a first region 31A and the second region 32A on the light-emitting surface can be further increased.

As the light absorbing member 70, for example, a gray or black resin in which a black pigment such as carbon black or titanium black is contained in a resin is preferable. Examples of the resin that can be used include a fluorine resin, an acrylic resin, a silicone resin, an epoxy resin, and a urethane resin. Specifically, as the light absorbing member 70, for example, a silicone resin containing carbon black in a range from 0.1 mass % to 10 mass % is preferable. For example, the thickness of the light absorbing member 70 is preferably in a range from 10 μm to 40 μm, more preferably in a range from 20 μm to 30 μm. Note that when the light source 5 includes the wavelength conversion member 20, the thickness of the light absorbing member 70 is preferably less than the thickness of the wavelength conversion member 20.

The light absorbing member 70 is disposed on the second surface 300b of a light-transmissive member 300 having a flat plate shape, for example, before the step S11 of disposing the wavelength conversion member. Alternatively, after the light-transmissive member 300 is singulated, the light absorbing member 70 may be disposed before the step S13 of disposing the light-transmissive member.

The light absorbing member 70 can be disposed by, for example, printing, spray coating, or the like. Furthermore, the light absorbing member 70 having a plate shape may be prepared and directly joined to the light-transmissive member 30A or may be joined to the light-transmissive member 30A by using a known adhesive member.

A large part of light emitted from the light source 5 is emitted from a first surface 30Aa of the light-transmissive member 30A on the wavelength conversion member 20 side.

On the other hand, since the first region 31A of the light-transmissive member 30A is spaced from the light source 5 in a top view, the amount of light emitted from the first surface 30Aa side of the light-transmissive member 30A on the first region 31A side is reduced. Moreover, a part of the light emitted from the light source 5 is reflected by the groove 35 and/or the covering members 40 disposed in the groove 35, returns to the wavelength conversion member 20 side, and is emitted from the first surface 30Aa side of the light-transmissive member 30A on the wavelength conversion member 20 side. Moreover, out of the light emitted from the light source 5, a part of light propagating through the light-transmissive member 30A is absorbed by the light absorbing member 70. Thus, the amount of light emitted from the second region 32A side increases, and the amount of light emitted from the first region 31A side decreases. Therefore, the brightness on the first region 31A side of the light-emitting surface of the light-emitting device 100B is less, and the brightness on the second region 32A side of the light-emitting surface is relatively high.

### Fourth Embodiment

FIG. 7 is a cross-sectional view schematically illustrating a light-emitting device according to a fourth embodiment.

The configuration of a light-emitting device 100C is different from the configuration of the light-emitting device 100B of the third embodiment in that the light-emitting device 100C includes a light diffusion member 80 disposed on the first surface 30Aa of the light-transmissive member 30A.

As illustrated in FIG. 7, the light diffusion member 80 is disposed on the first surface 30Aa of the light-transmissive member 30A and the upper surface of the covering member 40.

Since the light-emitting device 100C includes the light diffusion member 80, light emitted from the light source 5 is diffused by the light diffusion member 80, and the boundary between the first region 31A side and the second region 32A side in the light emitted from the light-emitting device 100C can be made less visible. Moreover, since the light diffusion member 80 covers the upper surface of the covering member 40, the boundary between the light-transmissive member 30A and the covering member 40 can be made less visible. Thus, for example, when the light-emitting device 100C is used as a light source for an automobile headlight, illuminance changes in an irradiation range can be smoothed.

The light diffusion member 80 is made of, for example, a light diffusion material contained in a light-transmissive material such as a resin, glass, or an inorganic material and molded into a plate shape. As the resin, glass, and light diffusion material, those exemplified for the light-transmissive member can be used. For example, the thickness of the light diffusion member 80 is preferably in a range from 10 μm to 100 μm, more preferably in a range from 20 μm to 50 μm.

The light diffusion member 80 is disposed on the first surface 30Aa of the light-transmissive member 30A and the upper surface of the covering member 40, for example, after the step S14 of disposing the covering member.

The light diffusion member 80 can be joined to the first surface 30Aa of the light-transmissive member 30A and the upper surface of the covering member 40 by using, for example, a known adhesive member. For example, the light diffusion member 80 may cover the first surface 30A of the light-transmissive member 30Aa and the upper surface of the covering member 40 by electrodeposition, printing, spray coating, or the like.

### Fifth Embodiment

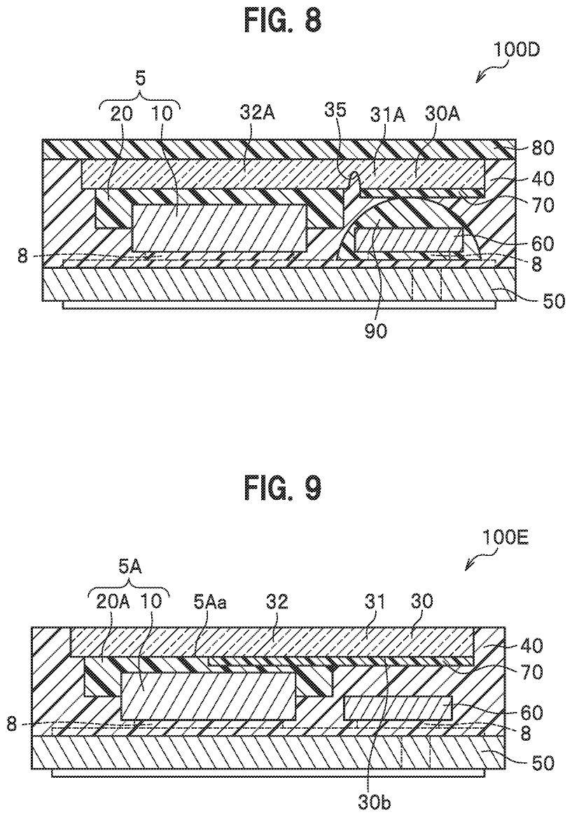

FIG. 8 is a cross-sectional view schematically illustrating a light-emitting device according to a fifth embodiment.

The configuration of a light-emitting device 100D is different from the configuration of the light-emitting device 100C of the fourth embodiment in that the light-emitting device 100D includes a support member 90 disposed on the wiring substrate 50 and supporting the light-transmissive member 30A.

As illustrated in FIG. 8, the support member 90 covers the electronic component 60 and is disposed in contact with the light absorbing member 70 disposed on the light-transmissive member 30A. The support member 90 supports the first region 30A side of the light-transmissive member 31A via the light absorbing member 70; however, when the light-emitting device does not include the light absorbing member 70, the support member 90 may be in contact with the light-transmissive member 30A to support the first region 30A side of the light-transmissive member 31A. The support member 90 may cover a part of the electronic component 60 or may support the light-transmissive member 30A without covering the electronic component 60.

Since the light-emitting device 100D includes the support member 90, the first region 31A side of the light-transmissive member 30A can be suppressed from being inclined toward the wiring substrate 50 side. Thus, the arrangement position of the light-transmissive member 30A can be stably held.

Examples of the support member 90 that can be used include a silicone resin and an epoxy resin. The support member 90 preferably uses a high-viscosity resin in order to maintain a height for supporting the light-transmissive member 30A. For example, the support member 90 preferably uses a resin having a viscosity in a range from 200 Pa·s to 800 Pa·s at 25° C.

The support member 90 is disposed on the wiring substrate 50, for example, before the step S13 of disposing the light-transmissive member. The support member 90 can be disposed by potting, for example.

### Sixth Embodiment

FIG. 9 is a cross-sectional view schematically illustrating a light-emitting device according to a sixth embodiment.

The configuration of a light-emitting device 100E is different from the configuration of the light-emitting device 100 of the first embodiment in that the light-emitting device 100E includes a light absorbing member 70 between a light source 5A and the light-transmissive member 30.

As illustrated in FIG. 9, on the second surface 30b of the light-transmissive member 30, the light absorbing member 70 is disposed over a region from the vicinity of the center of the upper surface 5Aa of the light source 5 to the first region 31 side of the light-transmissive member 30 such that the light absorbing member 70 partially overlaps the light source 5 in the top view. Note that in the light source 5A, a wavelength conversion member 20A is thinner in the region where the light absorbing member 70 is disposed than in a region where the light absorbing member 70 is not disposed, by the thickness of the light absorbing member 70.

Since the light-emitting device 100E includes the light absorbing member 70, a part of light emitted from the upper surface 5Aa of the light-emitting device 5A is absorbed by the light absorbing member 70. Out of the light emitted from the light source 5A, a part of light on the first region 31 side of the light-transmissive member 30 is absorbed by the light absorbing member 70. Therefore, the brightness of the first region 31 side of a light-emitting surface of the light-emitting device 100E is relatively less than the brightness on the second region 32 side. Thus, the brightness difference between the first region 31 side and the second region 32 side on the light-emitting surface can be further increased.

The light absorbing member 70 can be disposed on the second surface 300b of the light-transmissive member 300 having a flat plate shape, for example, before the step S11 of disposing the wavelength conversion member. Other matters related to the light absorbing member 70 are as described in the third embodiment.

As a modified example, a light-reflective member may be used instead of the light absorbing member 70. The same material as or similar material to the material of the covering member 40 can be used as the light-reflective member.

### Seventh Embodiment

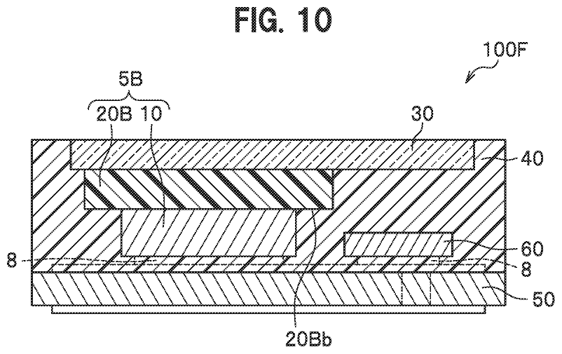

FIG. 10 is a cross-sectional view schematically illustrating a light-emitting device according to a seventh embodiment.

The configuration of a light-emitting device 100F is different from the configuration of the light-emitting device 100 of the first embodiment in that a wavelength conversion member 20B has no recessed portion on a first lower surface 20Bb and a part of the light-emitting element 10 is not disposed in the recessed portion.

As illustrated in FIG. 10, in a light source 5B, the light-emitting element 10 is disposed on the substantially flat first lower surface 20Bb of the wavelength conversion member 20B.

The light-emitting device 100F includes the wavelength conversion member 20B having a flat plate shape. As the wavelength conversion member 20B having a flat plate shape, a resin-molded body, glass, ceramics, a sintered body of a phosphor, or the like can be used. Thus, in the light-emitting device 100F, direct joining such as atomic diffusion joining or surface-activated joining can be preferably used as a joining method between the wavelength conversion member 20B and the light-emitting element 10 and/or a joining method between the wavelength conversion member 20B and the light-transmissive member 30.

The light-emitting element 10 and the wavelength conversion member 20B may be joined to each other via a known adhesive member. The light-emitting device may further include a light guide member in which the adhesive member described above extends to the lateral surface of the light-emitting element 10. As the light guide member, a light-transmissive resin can be used, for example. As the light guide member, an organic resin such as an epoxy resin, a silicone resin, a phenol resin, or a polyimide resin can be used, for example. Note that when the wavelength conversion member 20B to which the light-transmissive member 30 is joined is joined to the light-emitting element 10 via an adhesive member, the light-emitting device 100F preferably includes a support member 90 that supports the light-transmissive member 30, as in the fifth embodiment and the example illustrated in FIG. 8, in order to suppress the light-transmissive member 30 from being inclined due to its own weight.

The light-emitting device according to the present embodiment and the method for manufacturing the light-emitting device have been specifically described above by means of the embodiments for carrying out the invention, but the spirit of the present invention is not limited to these descriptions and should be interpreted broadly based on the appended claims. Various modifications, variations, and the like based on these descriptions are also included within the spirit of the present invention. The aforementioned embodiments can be implemented in combination with each other.

The wavelength conversion member may also have a layered structure with two or more layers. In that case, the phosphor concentration is the proportion of the phosphor to the total amount of the phosphor-containing layer in the wavelength conversion member. In the light-emitting device, a reflective film such as a dielectric multilayer film may be disposed on the upper surface of the wavelength conversion member or the light diffusion member. Thus, the brightness and luminous intensity of light emitted from a light-emitting region of the light-emitting device can be more easily adjusted.

Furthermore, in the method for manufacturing the light-emitting device, the order of some steps is not limited, and the order can be reversed. For example, after the light-emitting element is disposed on the wavelength conversion member, the light-transmissive member may be disposed on the wavelength conversion member. After the light source is disposed on the wiring substrate, the light-transmissive member may be disposed on the light source. Alternatively, after the light-emitting element is disposed on the wiring substrate, the wavelength conversion member may be disposed on the light-emitting element.

The light-emitting devices according to the embodiments of the present disclosure can be preferably utilized for vehicle lighting such as headlights. In addition, the light-emitting devices according to the embodiments of the present disclosure can be utilized for the light source for a backlight of a liquid crystal display, various types of lighting fixtures, a large display, various types of display devices for advertisements, destination information, and the like, and further, a digital video camera, image reading devices in a facsimile, a copy machine, a scanner, and the like, and a projector device, for example.

What is claimed is:

1. A light-emitting device comprising:
a light source including a light-emitting element, the light source having a light-emitting surface on an upper surface;
a light-transmissive member including a first surface and a second surface located on an opposite side of the first surface, the second surface of the light-transmissive member facing the upper surface of the light source; and
a covering member exposing the first surface of the light-transmissive member and covering lateral surfaces of the light-transmissive member and lateral surfaces of the light source, wherein
the lateral surfaces of the light source include a first lateral surface continuous with the upper surface and a second lateral surface located on an opposite side of the first lateral surface,
the lateral surfaces of the light-transmissive member include a first lateral surface located on the same side as the first lateral surface of the light source and a second lateral surface located on an opposite side of the first lateral surface, and
in a top view, a center of the upper surface of the light source is located closer to a side of the second lateral surface of the light-transmissive member than a center of the first surface of the light-transmissive member, and a length from the first lateral surface of the light source to the first lateral surface of the light-transmissive member is equal to or greater than ¼ of a length from the first lateral surface of the light-transmissive member to the second lateral surface of the light-transmissive member.

2. The light-emitting device according to claim 1, wherein
the light source includes a wavelength conversion member on the light-emitting element.

3. The light-emitting device according to claim 2, wherein
the wavelength conversion member includes a first upper surface constituting the upper surface of the light source, and a first lower surface located on an opposite side of the first upper surface,
the first lower surface includes a recessed portion, and
a part of the light-emitting element is disposed in the recessed portion.

4. The light-emitting device according to claim 1, wherein
the second surface of the light-transmissive member includes a groove between the first lateral surface and the second lateral surface of the light-transmissive member.

5. The light-emitting device according to claim 4, wherein
the light source is disposed between the groove and the second lateral surface of the light-transmissive member in the top view.

6. The light-emitting device according to claim 4, wherein
the groove divides the second surface of the light-transmissive member into two regions spaced apart from each other.

7. The light-emitting device according to claim 1, further comprising
a light absorbing member spaced apart from the light source and disposed on the second surface of the light-transmissive member.

8. The light-emitting device according to claim 1, further comprising
a light diffusion member disposed on the first surface of the light-transmissive member.

9. The light-emitting device according to claim 1, further comprising:
a wiring substrate on which the light source is disposed; and
an electronic component disposed on the wiring substrate and spaced apart from the light source.

10. The light-emitting device according to claim 1, further comprising:
a wiring substrate on which the light source is disposed; and
a support member disposed on the wiring substrate and supporting the light-transmissive member.

11. The light-emitting device according to claim 9, further comprising
a support member disposed on the wiring substrate and supporting the light-transmissive member.

12. The light-emitting device according to claim 11, wherein
the support member covers the electronic component.

13. The light-emitting device according to claim 12, wherein
the support member includes a silicon resin or epoxy resin.

14. The light-emitting device according to claim 5, further comprising
a light absorbing member disposed on the second surface of the light-transmissive member between the groove and the first lateral surface of the light-transmissive member in the top view.

15. The light-emitting device according to claim 7, wherein
the light absorbing member partially overlaps the light source in the top view.
